(19) United States
(12) Patent Application Publication
(10) Pub. No.: US 2024/0297172 A1
(43) Pub. Date: Sep. 5, 2024

(54) DISPLAY MODULE AND DISPLAY DEVICE

(71) Applicant: Xiamen Tianma Display Technology Co., Ltd., Xiamen (CN)

(72) Inventors: Yicheng CHEN, Xiamen (CN); Yicai CHEN, Xiamen (CN)

(73) Assignee: Xiamen Tianma Display Technology Co., Ltd., Xiamen (CN)

(21) Appl. No.: 18/662,338

(22) Filed: May 13, 2024

(30) Foreign Application Priority Data
Dec. 27, 2023 (CN) 202311823537.3

(51) Int. Cl. H01L 27/12

(52) U.S. Cl. CPC H01L 27/1218

(57) ABSTRACT

Provided are a display module and a display device. The display module includes an under-display structure and a display panel. The under-display structure includes a support insulating layer, a buffer layer, and a base, where the buffer layer is disposed on a side of the base, and the support insulating layer is disposed on the side of the buffer layer facing away from the base; and the display panel is disposed on the side of the support insulating layer facing away from the buffer layer. The display panel includes a substrate including polyimide. The Young's modulus of the support insulating layer is higher than the Young's modulus of the substrate.

### CROSS-REFERENCE TO RELATED APPLICATION(S)

This application claims priority to Chinese Patent Application No. 202311823537.3 filed with the China National Intellectual Property Administration (CNIPA) on Dec. 27, 2023, the disclosure of which is incorporated herein by reference in its entirety.

### TECHNICAL FIELD

Embodiments of the present disclosure relate to the field of display technologies, in particular, a display module and a display device.

### BACKGROUND

With the continuous development of display technologies, display modules have been widely used in people's production and life activities. However, display modules in the related art still have some technical problems to be alleviated urgently. For example, the structural stability of a display module requires to be represented.

### SUMMARY

Embodiments of the present disclosure provide a display module and a display device, and the Young's modulus of a support insulating layer is regulated to be relatively high so that the overall structural stability of the display module and the display effect of the display module are improved.

Embodiments of the present disclosure provide a display module including an under-display structure and a display panel.

The under-display structure includes a support insulating layer, a buffer layer, and a base, the buffer layer is disposed on a side of the base, and the support insulating layer is disposed on a side of the buffer layer facing away from the base; and the display panel is disposed on a side of the support insulating layer facing away from the buffer layer.

The display panel includes a substrate including polyimide.

The Young's modulus of the support insulating layer is higher than the Young's modulus of the substrate.

Embodiments of the present disclosure provide a display device including the display module described above.

### BRIEF DESCRIPTION OF DRAWINGS

To illustrate technical schemes in example embodiments of the present disclosure more clearly, drawings used in the description of the embodiments are briefly described below. Apparently, the described drawings are only part, not all, of drawings of the embodiments of the present disclosure to be described, and those of ordinary skill in the art may obtain other drawings based on the drawings described below on the premise that no creative work is done.

FIG. 1 is a structural diagram of a display module according to an embodiment of the present disclosure;

FIG. 2 is a structural diagram of a display panel according to an embodiment of the present disclosure;

FIG. 3 is a structural diagram of another display module according to an embodiment of the present disclosure;

FIG. 4 is a structural diagram of another display module according to an embodiment of the present disclosure;

FIG. 5 is a structural diagram of a support insulating layer in FIG. 4;

FIG. 6 is a structural diagram of another display module according to an embodiment of the present disclosure;

FIG. 7 is a structural diagram of a support insulating layer in FIG. 6;

FIG. 8 is a structural diagram of another display module according to an embodiment of the present disclosure;

FIG. 9 is a structural diagram of a support insulating layer in FIG. 8;

FIG. 10 is a structural diagram of a support insulating layer according to an embodiment of the present disclosure;

FIG. 11 is a structural diagram of another support insulating layer according to an embodiment of the present disclosure;

FIG. 12 is a structural diagram of another support insulating layer according to an embodiment of the present disclosure;

FIG. 13 is a structural diagram of another display module according to an embodiment of the present disclosure;

FIG. 14 is a structural diagram of a support insulating layer in FIG. 13;

FIG. 15 is a structural diagram of another display module according to an embodiment of the present disclosure;

FIG. 16 is a structural diagram of a support insulating layer in FIG. 15;

FIG. 17 is a structural diagram of another support insulating layer according to an embodiment of the present disclosure;

FIG. 18 is a structural diagram of another support insulating layer according to an embodiment of the present disclosure;

FIG. 19 is a structural diagram of another support insulating layer according to an embodiment of the present disclosure;

FIG. 20 is a structural diagram of another support insulating layer according to an embodiment of the present disclosure; and

FIG. 21 is a structural diagram of a display device according to an embodiment of the present disclosure.

### DETAILED DESCRIPTION

The present disclosure is further described in detail below in conjunction with drawings and embodiments. It is to be understood that the embodiments described herein are intended to illustrate the present disclosure and not to limit the present disclosure. Additionally, it is to be noted that for ease of description, only part, not all, of structures related to the present disclosure are illustrated in the drawings.

It is to be noted that terms such as “first” and “second” in the description, claims, and drawings of the present disclosure are used for distinguishing between similar objects and are not necessarily used for describing a particular order or sequence. It is to be understood that data used in this manner are interchangeable in appropriate cases so that the embodiments of the present disclosure described herein can be implemented in an order not illustrated or described herein. In addition, terms such as “including”, “having”, and any other variations thereof are intended to encompass a non-exclusive inclusion. For example, a system, product, or device that includes a series of units not only includes the expressly listed steps or units but may also include other units that are not expressly listed or are inherent to such a product or device.

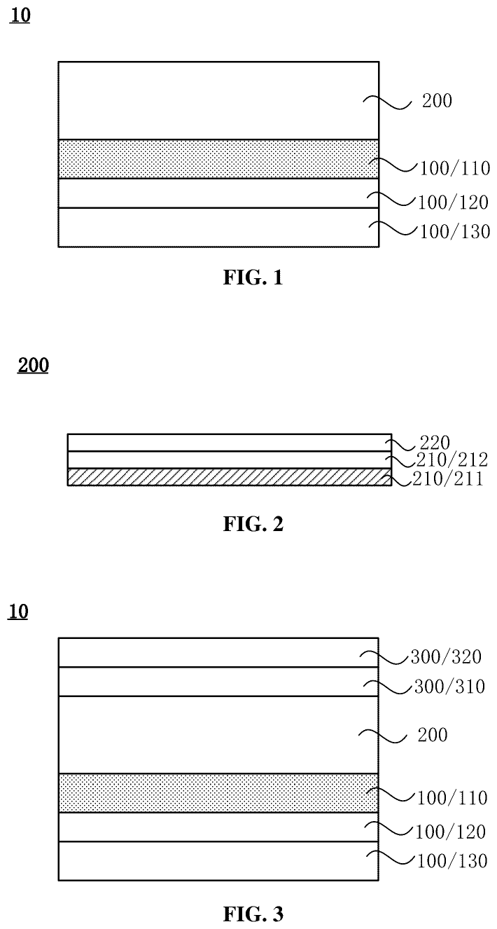

FIG. 1 is a structural diagram of a display module according to an embodiment of the present disclosure, FIG. 2 is a structural diagram of another display module according to an embodiment of the present disclosure, and FIG. 3 is a structural diagram of another display module according to an embodiment of the present disclosure. Referring to FIGS. 1 to 3, the embodiment of the present disclosure provides a display module 10 including an under-display structure 100 and a display panel 200. The under-display structure 100 includes a support insulating layer 110, a buffer layer 120, and a base 130; the buffer layer 120 is disposed on a side of the base 130, and the support insulating layer 110 is disposed on a side of the buffer layer 120 facing away from the base 130; the display panel 200 is disposed on a side of the support insulating layer 110 facing away from the buffer layer 120; the display panel 200 includes a substrate 211 including polyimide; and the Young's modulus of the support insulating layer 110 is higher than the Young's modulus of the substrate 211.

Referring to FIG. 1, the display module 10 includes the display panel 200. Multiple light-emitting elements (not shown in the figure) are included in a display region of the display panel 200, and multiple driver chips (not shown in the figure) are included in a non-display region of the display panel 200 and configured to provide signals and the like required by the light-emitting elements. Thus, the display panel 200 emits light and performs display, that is, the display module 10 implements a display function through the display panel 200. For example, the type of display panel 200 is not limited in embodiments of the present disclosure.

Further, the display module 10 also includes the under-display structure 100, the under-display structure 100 is disposed on the side of the display panel 200 and configured to support and protect the display panel 200. Referring to FIG. 1, the under-display structure 100 includes the support insulating layer 110, the buffer layer 120, and the base 130. The relative position relationships between the support insulating layer 110, the buffer layer 120, and the base 130 are described as follows: the buffer layer 120 is disposed on the side of the base 130, the support insulating layer 110 is disposed on the side of the buffer layer 120 facing away from the base 130, and the support insulating layer 110 in the under-display structure 100 faces the side of the display panel 200. The support insulating layer 110 is closer to the display panel 200 than the other films in the under-display structure 100. Therefore, the display panel 200 may be directly affected by a deformation of the structure of the under-display structure 100. If the structure of the support insulating layer 110 is stable, which may be understood as follows: the support insulating layer 110 does not easily deform under the action of conditions such as an external force, the structure of the attaching display panel 200 is not easily affected by the deformation of the support insulating layer 110, thereby ensuring the structural stability of the display panel 200 and further ensuring the display effect of the display module 10. For example, the base 130 in the under-display structure 100 may be made of a steel sheet and is configured to support the entire under-display structure 100. The buffer layer 120 in the under-display structure 100 may be made of a material with a certain viscosity so that the support insulating layer 110 is more stably disposed on the side of the base 130. In some embodiments, the under-display structure 100 may further include other film structures. In the display module 10, films of the under-display structure 100 may be adaptively adjusted according to actual requirements, which are not limited in embodiments of the present disclosure.

Referring to FIG. 2, the display panel 200 includes a substrate structure 210, the substrate structure 210 may include the substrate 211 (a material of the substrate 211 is polyimide) and other film structures (212 is used as an example in the figure). The number of films of the substrate structure 210, the order in which the films of the substrate structure 210 are disposed, and the like are not limited in embodiments of the present disclosure and may be adaptively adjusted according to actual requirements of the display panel 200. Further, referring to FIG. 2, the display panel 200 also includes an array layer 220, the array layer 220 includes a metal layer, an insulating layer, and the like that are stacked. Films of the array layer 220 are also not limited by embodiments of the present disclosure.

In the display module 10, in the case where the support insulating layer 110 is made of the polyimide, the polyimide has a low hardness, and therefore, the support insulating layer 110 of the polyimide generates a strong resilience force when an impacting object or another force impacts downward (the “downward” direction may refer to the direction from the display panel 200 to the under-display structure 100) during a bending test or another test on the display module 10, or the polyimide with a low hardness easily deforms under other conditions. Regardless of whether the support insulating layer 110 generates the resilience force or deforms, damage is caused to the screen of the attaching display panel 200, which affects the structural stability of the display panel 200 and further affects the display effect of the display module 10. In the display module 10 provided by embodiments of the present disclosure, the Young's modulus of the support insulating layer 110 is set to be higher than the Young's modulus of the substrate 211, that is, the hardness of the material of the support insulating layer 110 provided by embodiments of the present disclosure is higher than the hardness of a support insulating layer of the polyimide. In this manner, it can be ensured that the support insulating layer 110 does not easily deform and generates no resilience when the support insulating layer 110 is impacted by the external force. Thus, no damage is caused to the display panel 200, and the structural stability of the display panel 200 and the display effect of the display panel 200 are ensured, thereby ensuring the structural stability of the display module 10 and the display effect of the display module 10.

In some embodiments, the support insulating layer 110 includes glass.

The Young's modulus of the glass is higher than the Young's modulus of the polyimide, and the glass may be used for preparing the support insulating layer 110 so that it can be ensured that the support insulating layer 110 has a higher hardness.

In some embodiments, referring to FIG. 3, the display module 10 may further include an above-display structure 300, and the above-display structure 300 and the under-display structure 100 are disposed in two layers of the display panel 200 and configured to protect and support the display panel 200. Further, the above-display structure 300 may include an optical-adhesive layer 310 and a cover plate 320. Film relationships of the above-display structure 300 may be adaptively adjusted according to the actual requirements and are not limited in embodiments of the present disclosure.

In summary, the embodiment of the present disclosure provides the display module, where the display module includes the under-display structure and the display panel, the support insulating layer in the under-display structure attaches to the display panel, the display panel includes the substrate including the polyimide, and the Young's modulus of the support insulating layer is regulated to be higher than the Young's modulus of the substrate, that is, the Young's modulus of the support insulating layer is regulated to be higher so that the support insulating layer does not deform when the support insulating layer is affected by the external force. Further, the display panel is not affected by the support insulating layer in terms of deformation, thereby ensuring the overall structural stability of the display module. In addition, the impact on the display panel is reduced, thereby ensuring the display effect of the display module.

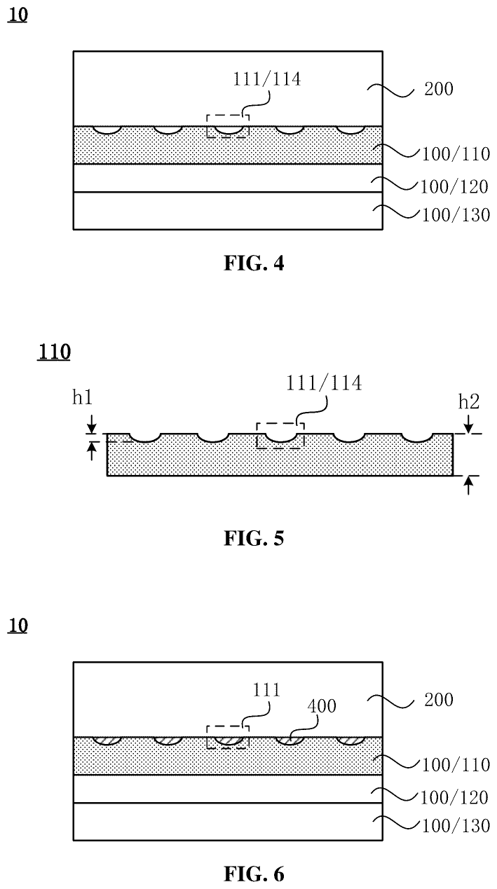

FIG. 4 is a structural diagram of another display module according to an embodiment of the present disclosure, and FIG. 5 is a structural diagram of a support insulating layer in FIG. 4. Referring to FIGS. 4 and 5, the support insulating layer 110 includes at least one groove 111, the total volume of the at least one groove 111 is v1, and the total volume of the support insulating layer 110 is v2, where 0<v1/v2≤40%.

Further, referring to FIGS. 4 and 5, the support insulating layer 110 may include multiple grooves 111, which may be understood as follows: part of the surface of the support insulating layer 110 is etched to form the multiple grooves 111. The grooves 111 are disposed so that stress dispersion can be performed on the external force transmitted to the support insulating layer 110, preventing the support insulating layer 110 from withstanding excessive pressure.

Further, the total volume of the multiple grooves 111 is v1, the total volume of the support insulating layer 110 is v2, and 0<v1/v2≤40%. The total volume of the multiple grooves 111 and the total volume of the support insulating layer 110 are set to have a certain proportional relationship. The multiple grooves 111 are disposed so that the external stress can be effectively dispersed, that is, 0<v1/v2. However, the total volume of the multiple grooves 111 does not need to be excessively large. If the total volume of the grooves 111 is excessively large, the overall Young's modulus of the support insulating layer 110 is affected, that is, the hardness of the support insulating layer 110 is affected, so v1/v2≤40%. Therefore, the grooves 111 mitigating the stress are disposed, but the total volume of the grooves 111 is set to be not excessively large and satisfies that 0<v1/v2≤40% so that the structural stability of the display module 10 can be better ensured.

With continued reference to FIGS. 4 and 5, along the thickness direction of the support insulating layer 110, the depth of a groove 111 is h1, and the thickness of the support insulating layer 110 is h2, where 0<h1≤h2/2.

Referring to FIG. 5, along the thickness direction of the support insulating layer 110, the depth of the groove 111 is less than the thickness of the support insulating layer 110, that is, the groove 111 prepared in the support insulating layer 110 does not penetrate through the support insulating layer 110. The grooves 111 may be disposed on the side of the support insulating layer 110 facing the display panel 200 or the side of the support insulating layer 110 facing the buffer layer 120, and the depth h1 of the grooves 111 and the depth h2 of the support insulating layer 110 satisfy that 0<h1≤h2/2. In the case of a known total volume relationship and depth relationship between the grooves 111 and the support insulating layer 110, the manner for disposing the grooves 111 may be adaptively adjusted, which represents a diversified design of the grooves 111. Thus, the structural stability of the display module 10 and the display effect of the display module 10 are ensured.

In some embodiments, 0<h1≤30 μm, and 30 μm<h2≤80 μm.

For example, the depth h1 of the grooves 111 may be 5 μm, 15 μm, 20 μm, or 30 μm, and h1 may be any value satisfying that 0<h1≤30 μm. The depth h2 of the support insulating layer 110 may be 40 μm, 50 μm, 70 μm, or 80 μm, and h2 may be any value satisfying that 30 μm<h2≤80 μm. It is to be noted that h1 and h2 need to satisfy that 0<h1≤h2/2 so that the overall structural stability of the display module 10 can be better ensured. That is, in the case where the depth relationship between the grooves 111 and the support insulating layer 110 is satisfied, the depth of the grooves 111 and the depth of the support insulating layer 110 may be selected according to the provided depth ranges, which represents the flexibility in the configuration of the grooves 111 and the support insulating layer 110.

FIG. 6 is a structural diagram of another display module according to an embodiment of the present disclosure, and FIG. 7 is a structural diagram of a support insulating layer in FIG. 6. Referring to FIGS. 6 and 7, the under-display structure 100 further includes a filling structure 400 disposed in the grooves 111. The viscosity of the filling structure 400 is greater than the viscosity of the support insulating layer 110.

Further, the under-display structure 100 also includes the filling structure 400 filled in the groove 111, and the viscosity of the filling structure 400 is greater than the viscosity of the support insulating layer 110. Thus, better adhesiveness between the part of the support insulating layer 110 provided with the filling structure 400 and the layer attaching to the support insulating layer 110 can be effectively ensured, and the support insulating layer 110 and the attaching layer are not easily detached from each other. Thus, the structural stability of the display module 10 is further ensured. For example, the filling structure 400 is made of an adhesive material.

For example, if the groove 111 is disposed on the surface of the side of the support insulating layer 110 facing the display panel 200, the filling structure 400 filled in the groove 111 can ensure that the support insulating layer 110 and the display panel 200 are not easily detached from each other. For example, if the groove 111 is disposed on the surface of the side of the support insulating layer 110 facing the buffer layer 120, the filling structure 400 filled in the groove 111 can ensure that the support insulating layer 110 and the buffer layer 120 are not easily detached from each other.

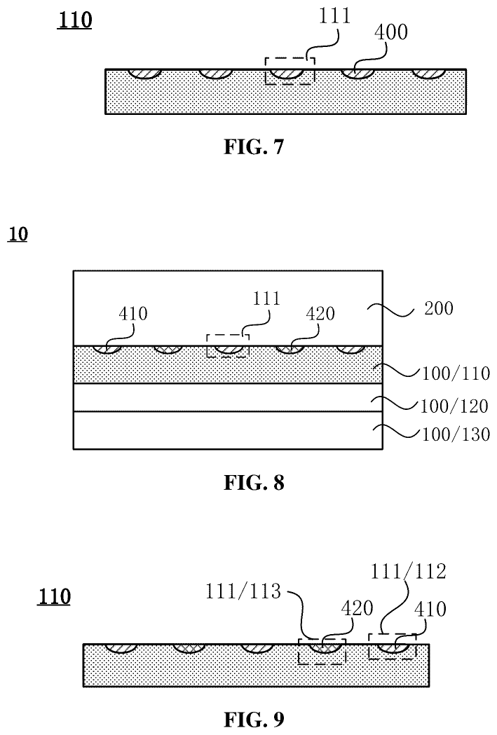

FIG. 8 is a structural diagram of another display module according to an embodiment of the present disclosure, and FIG. 9 is a structural diagram of a support insulating layer in FIG. 8. Referring to FIGS. 8 and 9, the grooves 111 include first grooves 112 and second grooves 113, and the filling structure 400 includes first filling units 410 and second filling units 420. The first filling units 410 are disposed in the first grooves 112, and the second filling units 420 are disposed in the second grooves 113, and the Young's modulus of the first filling units 410 is higher than the Young's modulus of the second filling units 420.

Further, referring to FIGS. 8 and 9, the filling structure 400 includes the first filling units 410 and the second filling units 420, the Young's modulus of the first filling units 410 is different from the Young's modulus of the second filling units 420, and the Young's modulus of the first filling units 410 is higher than the Young's modulus of the second filling units 420, that is, the hardness of the first filling units 410 is higher than the hardness of the second filling units 420.

Further, each of the viscosity of the first filling units 410 and the viscosity of the second filling units 420 is greater than the viscosity of the support insulating layer 110, that is, the first filling units 410 and the second filling units 420 are each made of a viscous material. The higher the hardness of the viscous material, the less the viscosity of the viscous material. Therefore, in the case where the Young's modulus of the first filling units 410 is higher than the Young's modulus of the second filling units 420, the viscosity of the second filling units 420 is greater than the viscosity of the first filling units 410. For the support insulating layer 110, the second filling units 420 are added in the grooves 111 so that the adhesion force between the support insulating layer 110 and an adjacent film can be mainly ensured, thereby preventing a detachment. The slightly harder first filling units 410 are filled in the grooves 111 in the case where the second filling units 420 are disposed so that the hardness of the support insulating layer 110 is balanced; thus, the structural stability of the display module 10 is ensured.

Further, the grooves 111 include the first grooves 112 and the second grooves 113, the first filling units 410 are filled in the first grooves 112, and the second filling units 420 are filled in the second grooves 113. The first grooves 112 and the second grooves 113 are disposed, which may be understood as follows: filling structures 400 having different Young's moduli are disposed in different grooves 111.

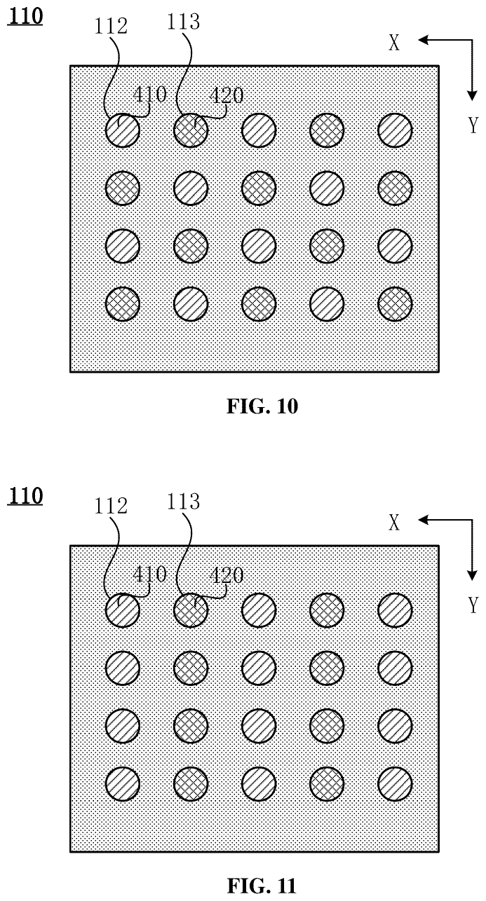

FIG. 10 is a structural diagram of a support insulating layer according to an embodiment of the present disclosure, and FIG. 11 is a structural diagram of another support insulating layer according to an embodiment of the present disclosure. Referring to FIGS. 10 and 11, the first grooves 112 are uniformly distributed in the support insulating layer 110, and the second grooves 113 are uniformly distributed in the support insulating layer 110.

Referring to FIG. 10, in the support insulating layer 110, the first grooves 112 and the second grooves 113 are uniformly distributed on the surface of the support insulating layer 110 separately. In the figure, an example in which both the first grooves 112 and the second grooves 113 are disposed on the same surface is used for description. For example, in FIG. 10, it may be considered that the first grooves 112 and the second grooves 113 are disposed on the surface of the side of the support insulating layer 110 facing the display panel 200. In some embodiments, the first grooves 112 and the second grooves 113 may be disposed on the surfaces of two sides of the support insulating layer 110, respectively, which is not limited in embodiments of the present disclosure.

For example, referring to FIG. 10, along either one of a first direction X and a second direction Y (the first direction X and the second direction Y intersect with each other and are parallel to the extension direction of the support insulating layer 110), at least one second groove 113 is included between two adjacent first grooves 112. Thus, it represents that the first grooves 112 are uniformly distributed on the surface of the support insulating layer 110, and it may also represent that the second grooves 113 are also uniformly distributed on the surface of the support insulating layer 110. Referring to FIG. 11, multiple first grooves 112 are arranged along the second direction Y to form one column of first grooves 112, and multiple columns of first grooves 112 are arranged along the first direction X; and multiple second grooves 113 are arranged along the second direction Y to form one column of second grooves 113, and multiple columns of second grooves 113 are arranged along the first direction X, where at least one column of second grooves 113 is included between two adjacent columns of first grooves 112. In this manner, the first grooves 112 and the second grooves 113 are uniformly arranged.

It is to be noted that FIG. 10 and FIG. 11 show only the two manners in which the first grooves 112 and the second grooves 113 are arranged. Not all manners for arranging the first grooves 112 and the second grooves 113 are shown. It is ensured that the first grooves 112 and the second grooves 113 are uniformly distributed on the surface of the support insulating layer 110, that is, the first filling units 410 and the second filling units 420 are uniformly distributed on the surface of the support insulating layer 110. Thus, it can be ensured that the hardness of the support insulating layer 110 is balanced, and it can also be ensured that the adhesion force between the support insulating layer 110 and adjacent films is balanced.

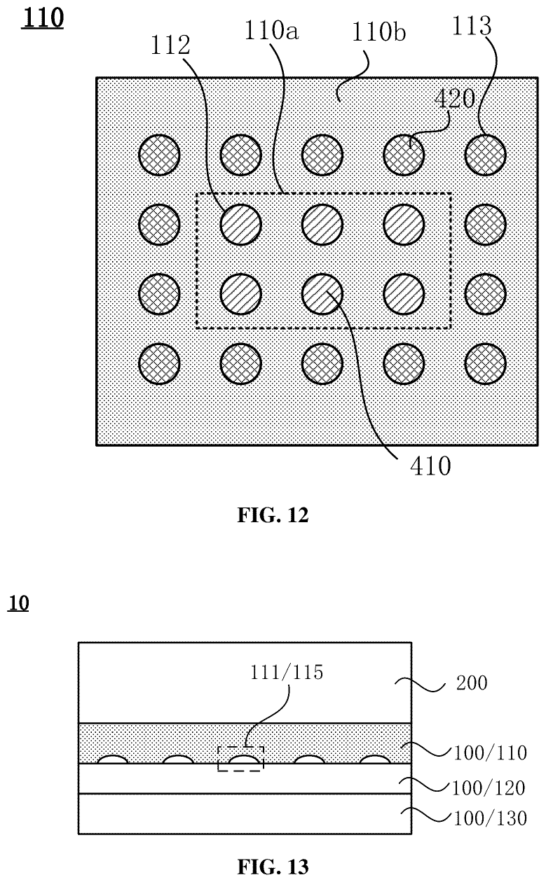

FIG. 12 is a structural diagram of another support insulating layer according to an embodiment of the present disclosure. Referring to FIG. 12, the support insulating layer 110 includes a first region 110a and a second region 110b, the first region 110a includes the center of the support insulating layer 110, the second region 110b surrounds the first region 110a, the first grooves 112 are disposed in the first region 110a, and the second grooves 113 are disposed in the second region 110b.

Referring to FIG. 12, the support insulating layer 110 includes the first region 110a and the second region 110b, the first region 110a includes the center of the support insulating layer 110, that is, the first region 110a is a central region of the support insulating layer 110, and the second region 110b surrounds the first region 110a, that is, the second region 110b is an edge region of the support insulating layer 110.

Further, the first filling units 410 are filled in the first grooves 112 so that the first filling units 410 are distributed in the first region 110a, and the second filling units 420 are filled in the second grooves 113 so that the second filling units 420 are distributed in the second region 110b. It is to be understood that the hardness of the first filling units 410 is higher than the hardness of the second filling units 420, and the first filling units 410 are distributed at the center of the support insulating layer 110, which helps ensure the hardness of the central region of the support insulating layer 110. The viscosity of the second filling units 420 is greater than the viscosity of the first filling units 410, and the second filling units 420 are disposed in the edge region of the support insulating layer 110, which helps ensure a strong adhesion force between the edge region of the support insulating layer 110 and the adjacent films. For the support insulating layer 110, the central region of the support insulating layer 110 is subjected to more impact of the external force than the edge region of the support insulating layer 110. Therefore, the hardness of the first region 110a may be ensured as high as possible. The degree of detachment in the edge region of the support insulating layer 110 is greater than the degree of detachment in the central region of the support insulating layer 110. Therefore, the viscosity of the second region 110b may be ensured as high as possible. That is, in the embodiment of the present disclosure, the manner for distributing the filling structure 400 is adaptively adjusted according to different requirements of different regions of the support insulating layer 110, thereby better ensuring the structural stability of the display module 10.

In some embodiments, the first filling units 410 include a first light-curing adhesive, and the second filling units 420 include a second light-curing adhesive, and the first light-curing adhesive and the second light-curing adhesive have different curing time and/or different curing light intensities.

Each of the first filling units 410 and the second filling units 420 may be a light-curing adhesive. The first filling units 410 and the second filling units 420 may be prepared with different technique parameters when the first filling units 410 and the second filling units 420 are cured so that the first filling units 410 and the second filling units 420 have different viscosity and different hardness. The first filling units 410 include the first light-curing adhesive, and the second filling units 420 include the second light-curing adhesive. The Young's modulus of the first light-curing adhesive is higher than the Young's modulus of the second light-curing adhesive. The curing time of the first light-curing adhesive may be adjusted to be longer than the curing time of the second light-curing adhesive, or the curing light intensity of the first light-curing adhesive may be adjusted to be greater than the curing light intensity of the second light-curing adhesive. For example, light curing may be performed through ultraviolet light. That is, the irradiation time of the ultraviolet light or the light intensity of the ultraviolet light is adjusted to be different so that the difference in the Young's modulus between the first curing adhesive and the second curing adhesive is implemented. Thus, the Young's modulus of the first filling units 410 is higher than the Young's modulus of the second filling units 420.

For example, if a preparation technique with different curing time is used, the first filling units 410 may be first filled in the first grooves 112, then the second filling units 420 are filled in the second grooves 113 in a process where the first filling units 410 are irradiated, and next, the first filling units 410 and the second filling units 420 are irradiated synchronously. Thus, it can be ensured that the irradiation time of the first filling units 410 is longer than the irradiation time of the second filling units 420. If a preparation technique with different curing light intensities is used, the second filling units 420 may be shielded by a light-shielding material when the light curing is performed on the first filling units 410, then an irradiation device is replaced, and the light curing is performed on the second filling units 420 after the first filling units 410 are shielded by the light-shielding material.

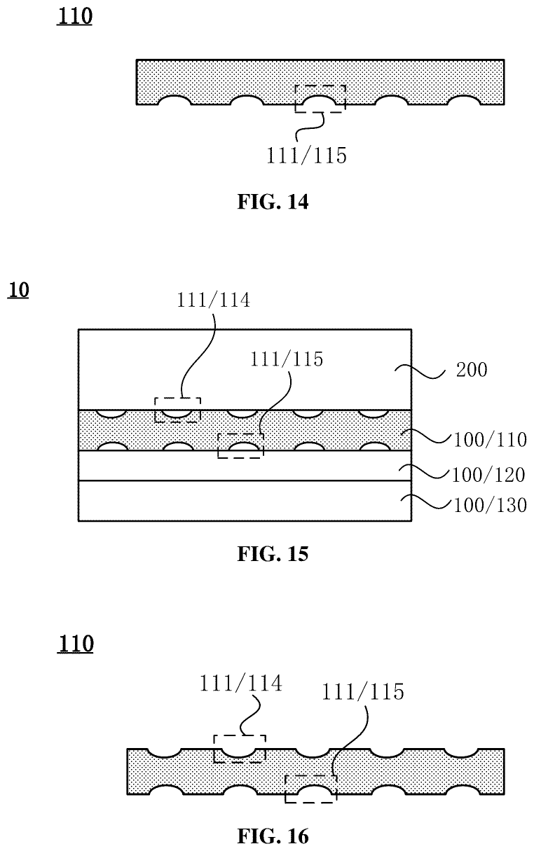

FIG. 13 is a structural diagram of another display module according to an embodiment of the present disclosure, FIG. 14 is a structural diagram of a support insulating layer in FIG. 13, FIG. 15 is a structural diagram of another display module according to an embodiment of the present disclosure, and FIG. 16 is a structural diagram of the support insulating layer in FIG. 15. Referring to FIG. 4, FIG. 5, and FIGS. 13 to 16, the grooves 111 include a third groove 114 and/or a fourth groove 115, the third groove 114 penetrates through the surface of the side of the support insulating layer 110 facing the display panel 200, and the fourth groove 115 penetrates through the surface of the side of the support insulating layer 110 facing the buffer layer 120.

The grooves 111 may be etched on the surface of one side of the support insulating layer 110 or the surfaces of the two sides of the support insulating layer 110. The grooves 111 are disposed so that the external force transmitted to the support insulating layer 110 can be mitigated, thereby ensuring the structural stability of the support insulating layer 110.

The grooves 111 may include the third groove 114 and/or the fourth groove 115, the third groove 114 penetrates through the surface of the side of the support insulating layer 110 facing the display panel 200, and the fourth groove 115 penetrates through the surface of the side of the support insulating layer 110 facing the buffer layer 120, which may be understood as follows: the third groove 114 and the fourth groove 115 are disposed on the two sides of the support insulating layer 110 along the thickness direction of the support insulating layer 110.

For example, referring to FIGS. 4 and 5, the grooves 111 include only the third groove 114, and an external force transmitted from the side of the display panel 200 to the side of the under-display structure 100 may be partially dispersed, thereby further preventing the support insulating layer 110 from generating a deformation such as a resilience toward the side facing the display panel 200. For example, referring to FIGS. 13 and 14, the grooves 111 include only the fourth groove 115, and an external force transmitted from the side of the under-display structure 100 to the side of the display panel 200 may be partially dispersed, thereby further preventing the support insulating layer 110 from generating a deformation such as a resilience toward the side facing away from the display panel 200. Referring to FIGS. 15 and 16, the grooves 111 may include both the third groove 114 and the fourth groove 115, and at the same time, an external force transmitted from the side of the display panel 200 to the side of the under-display structure 100 and an external force transmitted from the side of the under-display structure 100 to the side of the display panel 200 may be partially dispersed, thereby preventing the support insulating layer 110 from generating deformations in two directions facing the display panel 200 and facing away from the display panel 200. Thus, the structural stability of the display panel 10 is ensured.

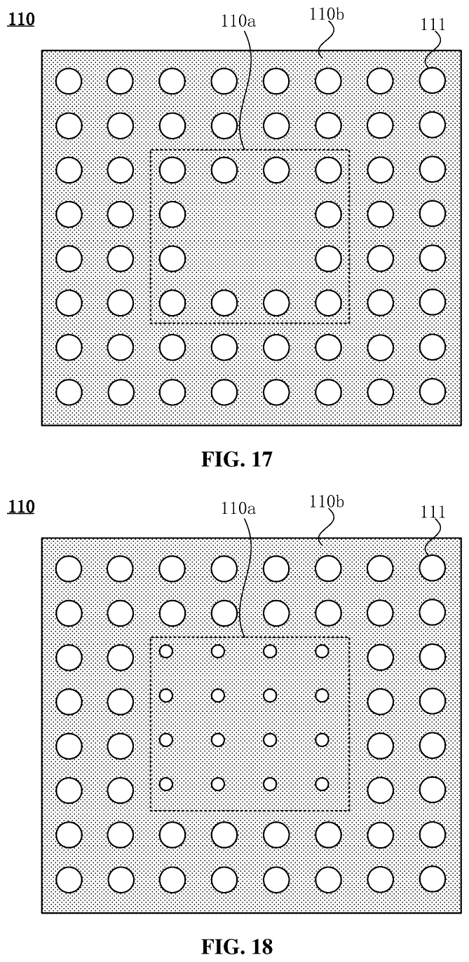

FIG. 17 is a structural diagram of another support insulating layer according to an embodiment of the present disclosure, and FIG. 18 is a structural diagram of another support insulating layer according to an embodiment of the present disclosure. Referring to FIGS. 17 and 18, the support insulating layer 110 includes a first region 110a and a second region 110b, the first region 110a includes the center of the support insulating layer 110, the second region 110b surrounds the first region 110a, and in a unit area, the sum of volumes of grooves 111 in the first region 110a is less than the sum of volumes of grooves 111 in the second region 110b.

In the case where the sum of the volumes of the grooves 111 disposed in the support insulating layer 110 having a higher hardness is less, it can be ensured that the support insulating layer 110 has a sufficient hardness. Thus, the external force transmitted to the support insulating layer 110 can be resisted, and the support insulating layer 110 is prevented from deforming. As described above, in the case where the grooves 111 disposed in the support insulating layer 110 do not affect the overall hardness of the support insulating layer 110 to a greater degree (the proportional relationship between the total volume of the grooves 111 and the total volume of the support insulating layer 110 is satisfied), more grooves 111 are provided so that part of the external force transmitted to the support insulating layer 110 can be effectively dispersed. In addition, when the filling structure with the viscosity is added in the grooves 111, a detachment of the whole structure can be prevented.

Further, referring to FIGS. 17 and 18, the support insulating layer 110 includes the first region 110a as the central region and the second region 110b as the edge region. The external force transmitted to the support insulating layer 110 requires to be dispersed faster in the edge region while the central region requires a higher hardness. Thus, the grooves 111 may be disposed and distributed more in the second region 110b so that it is ensured that the support insulating layer 110 can disperse the transmitted external force.

The sum of the volumes of the grooves 111 is regulated in the unit area, the sum of the volumes of the grooves 111 in the central region of the support insulating layer 110 is set to be less so that the hardness of the support insulating layer 110 is ensured, and the sum of the volumes of the grooves 111 in the edge region of the support insulating layer 110 is set to be greater so that it can be ensured that the support insulating layer 110 disperses the transmitted external force. In conjunction with the resistance and dispersion of the external force by the support insulating layer 110, the sum of the volumes of the grooves 111 may be adjusted separately in each region, thereby ensuring the structural stability of the display module 10.

The difference between the sum of the volumes of the grooves 111 disposed in the first region 110a and the sum of the volumes of the grooves 111 disposed in the second region 110b may be adjusted in different manners.

In some embodiments, with continued reference to FIG. 17, in the unit area, the number of grooves 111 in the first region 110a is less than the number of grooves 111 in the second region 110b.

Referring to FIG. 17, in the unit area, the number of grooves 111 in the first region 110a is less than the number of grooves 111 in the second region 110b. The numbers of the grooves 111 in different regions are adjusted to be different from each other so that the sums of the volumes of the grooves 111 in different regions are different from each other.

In some embodiments, with continued reference to FIG. 18, the average volume of the grooves 111 in the first region 110a is less than the average volume of the grooves 111 in the second region 110b.

Referring to FIG. 18, in the unit area, the average volume of the grooves 111 in the first region 110a is less than the average volume of the grooves 111 in the second region 110b, where an average volume may be considered as a ratio of the sum of volumes of n grooves 111 to n. The average volumes of grooves 111 in different regions are adjusted to be different so that the sums of the volumes of the grooves 111 in different regions are different from each other.

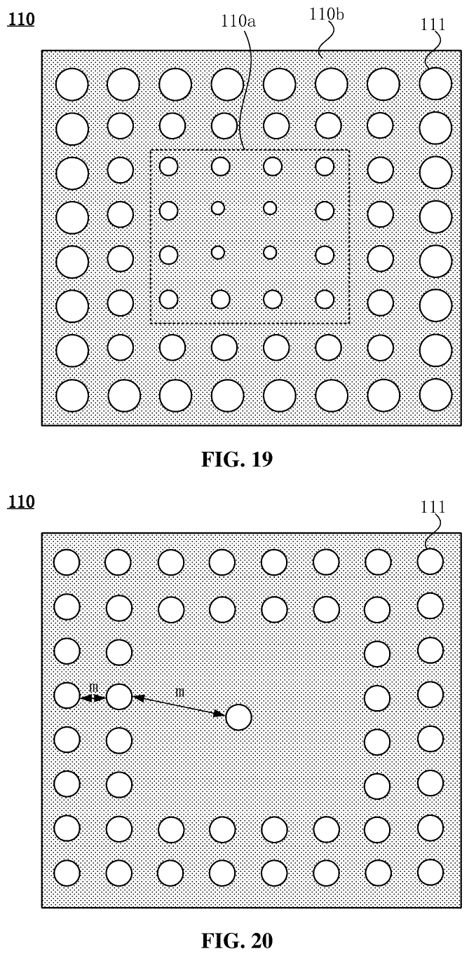

FIG. 19 is a structural diagram of another support insulating layer according to an embodiment of the present disclosure. Referring to FIG. 19, in any two of the grooves 111 within the first region 110a, the volume of one groove 111 facing the center of the support insulating layer 110 is less than the volume of the other groove 111 facing away from the center of the support insulating layer 110, and in any two of the grooves 111 within the second region 110b, the volume of one groove 111 facing the first region 110a is less than the volume of the other groove 111 facing away from the first region 110a.

Referring to FIG. 19, in any two of the grooves 111 within the first region 110a, the volume of one groove 111 facing the center of the support insulating layer 110 is less than the volume of the other groove 111 facing away from the center of the support insulating layer 110, which may be understood as an inside-out gradual increase in the volumes of the grooves 111 within the first region 110a, that is, the difference in the volumes of the grooves 111 may be configured to be graded. Similarly, in any two of the grooves 111 within the second region 110b, the volume of one groove 111 facing the first region 110a is less than the volume of the other groove 111 facing away from the first region 110a, which may be understood as an inside-out gradual increase in the volumes of the grooves 111 within the second region 110b, that is, the difference in the volumes of the grooves 111 may be configured to be graded. Thus, the grooves 111 are disposed in flexible manners.

FIG. 20 is a structural diagram of another support insulating layer according to an embodiment of the present disclosure. Referring to FIG. 20, a gap m is included between two adjacent grooves 111; in any two gaps m, the width of one gap m facing the center of the support insulating layer 110 is greater than the width of the other gap m facing away from the center of the support insulating layer 110.

Further, the gap m is included between two adjacent grooves 111. The size of the gap m is adjusted so that the distribution of the grooves 111 in the support insulating layer 110 can be adjusted. Referring to FIG. 20, in any two gaps m, the width of one gap m facing the center of the support insulating layer 110 is greater than the width of the other gap m facing away from the center of the support insulating layer 110. That is, it may be considered that in the support insulating layer 110, grooves 111 distributed closer to the center of the support insulating layer 110 are sparser, and grooves 111 distributed farther from the edge of the support insulating layer 110 are sparser. That is, it may be understood that the distribution gap m of the grooves 111 may also be configured to gradually change. Thus, the grooves 111 are disposed in flexible manners.

With continued reference to FIG. 20, the gap is denoted by m, where 10 μm≤m≤20 μm.

For example, the gap m between two adjacent grooves 111 may be 10 μm, 12 μm, 15 μm, or 20 μm, that is, the gap m may be any value satisfying that 10 μm≤m≤20 μm.

In the embodiments of the present disclosure, the grooves 111 may be disposed in multiple manners. Only several manners for disposing the grooves 111 are used as examples for description in FIGS. 10 to 20. The manners in which the grooves 111 are disposed may be adaptively adjusted according to the actual requirements, which are not enumerated in embodiments of the present disclosure.

In some embodiments, the grooves 111 include one of circular grooves, elliptical grooves, or polygonal grooves.

Referring to FIGS. 10 to 20, an example in which all of the grooves 111 are circular is used for description. For the shape of the grooves 111, the grooves 111 may be one of the elliptical grooves or the polygonal grooves, or different shapes of grooves 111 may be included in the same support insulating layer 110. The shape of the grooves 111 may be adaptively adjusted according to the actual requirements or different etching techniques, which is not limited in embodiments of the present disclosure.

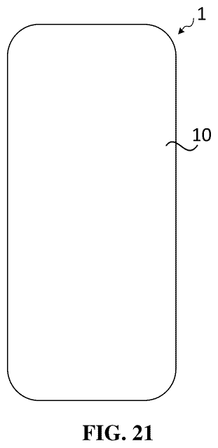

Based on the same inventive concept, an embodiment of the present disclosure further provides a display device. FIG. 21 is a structural diagram of a display device according to the embodiment of the present disclosure. As shown in FIG. 21, the display device 1 includes the display module 10 described in any one of the preceding embodiments, thereby having the corresponding beneficial effects in the preceding embodiments. The details are not repeated here. For example, the display device 1 may be an electronic device such as a mobile phone, a computer, a smart wearable device (for example, a smart watch), and an onboard display device, which is not limited in the embodiment of the present disclosure.

It is to be noted that the preceding are only embodiments of the present disclosure and technical principles used therein. It is to be understood by those skilled in the art that the present disclosure is not limited to the embodiments described herein. For those skilled in the art, various apparent modifications, adaptations, and substitutions can be made without departing from the scope of the present disclosure. Therefore, while the present disclosure is described in detail through the preceding embodiments, the present disclosure is not limited to the preceding embodiments and may include more equivalent embodiments without departing from the inventive concept of the present disclosure. The scope of the present disclosure is determined by the scope of the appended claims.

What is claimed is:

1. A display module, comprising an under-display structure and a display panel;
wherein the under-display structure comprises a support insulating layer, a buffer layer, and a base, wherein the buffer layer is disposed on a side of the base, and the support insulating layer is disposed on a side of the buffer layer facing away from the base; and the display panel is disposed on a side of the support insulating layer facing away from the buffer layer;
the display panel comprises a substrate comprising polyimide; and
a Young's modulus of the support insulating layer is higher than a Young's modulus of the substrate.

2. The display panel according to claim 1, wherein the support insulating layer comprises at least one groove;
wherein a total volume of the at least one groove is v1, and a total volume of the support insulating layer is v2;
wherein 0<v1/v2≤40%.

3. The display module according to claim 2, wherein along a thickness direction of the support insulating layer, a depth of the at least one groove is h1, and a thickness of the support insulating layer is h2;
wherein 0<h1≤h2/2.

4. The display module according to claim 3, wherein 0<h1≤30 μm, and 30 μm<h2≤80 μm.

5. The display module according to claim 2, wherein the under-display structure further comprises a filling structure disposed in the at least one groove;
wherein a viscosity of the filling structure is greater than a viscosity of the support insulating layer.

6. The display module according to claim 5, wherein the at least one groove comprises first grooves and second grooves, and the filling structure comprises first filling units and second filling units, wherein the first filling units are disposed in the first grooves, and the second filling units are disposed in the second grooves;
wherein a Young's modulus of the first filling units is higher than a Young's modulus of the second filling units.

7. The display module according to claim 6, wherein the first grooves are uniformly distributed in the support insulating layer, and the second grooves are uniformly distributed in the support insulating layer.

8. The display module according to claim 6, wherein the support insulating layer comprises a first region and a second region, wherein the first region comprises a center of the support insulating layer, and the second region surrounds the first region; and
the first grooves are disposed in the first region, and the second grooves are disposed in the second region.

9. The display module according to claim 6, wherein the first filling units comprise a first light-curing adhesive, and the second filling units comprise a second light-curing adhesive;
wherein the first light-curing adhesive and the second light-curing adhesive have at least one of different curing light intensities or different curing time.

10. The display module according to claim 2, wherein the at least one groove comprises at least one of a third groove or a fourth groove;
wherein the third groove penetrates through a surface of a side of the support insulating layer facing the display panel; and
the fourth groove penetrates through a surface of a side of the support insulating layer facing the buffer layer.

11. The display module according to claim 2, wherein the support insulating layer comprises a first region and a second region, wherein the first region comprises a center of the support insulating layer, and the second region surrounds the first region; and
in a unit area, a sum of volumes of grooves in the first region is less than a sum of volumes of grooves in the second region.

12. The display module according to claim 11, wherein in the unit area, a number of the grooves in the first region is less than a number of the grooves in the second region.

13. The display module according to claim 11, wherein an average volume of the grooves in the first region is less than an average volume of the grooves in the second region.

14. The display module according to claim 11, wherein
in any two of the grooves within the first region, a volume of one groove facing the center of the support insulating layer is less than a volume of another groove facing away from the center of the support insulating layer; and
in any two of the grooves within the second region, a volume of one groove facing the first region is less than a volume of another groove facing away from the first region.

15. The display panel according to claim 2, wherein a gap is provided between two adjacent grooves;
wherein in any two gaps, a width of one gap facing a center of the support insulating layer is greater than a width of another gap facing away from a center of the support insulating layer.

16. The display module according to claim 15, wherein the gap is denoted by m, wherein 10 μm≤m≤20 μm.

17. The display module according to claim 2, wherein the at least one groove comprises one of a circular groove, an elliptical groove, or a polygonal groove.

18. The display panel according to claim 1, wherein the support insulating layer comprises glass.

19. A display device, comprising a display module,
wherein the display module comprises an under-display structure and a display panel;
wherein the under-display structure comprises a support insulating layer, a buffer layer, and a base, wherein the buffer layer is disposed on a side of the base, and the support insulating layer is disposed on a side of the buffer layer facing away from the base; and the display panel is disposed on a side of the support insulating layer facing away from the buffer layer; the display panel comprises a substrate comprising polyimide; and a Young's modulus of the support insulating layer is higher than a Young's modulus of the substrate.

20. The display device according to claim 19, wherein the support insulating layer comprises at least one groove;
wherein a total volume of the at least one groove is v1, and a total volume of the support insulating layer is v2;
wherein 0<v1/v2≤40%.
